(19) United States
(12) Patent Application Publication
(10) Pub. No.: US 2016/0005912 A1
(43) Pub. Date: Jan. 7, 2016

(54) CIGS FILM PRODUCTION METHOD, AND CIGS SOLAR CELL PRODUCTION METHOD USING THE CIGS FILM PRODUCTION METHOD

(71) Applicant: NITTO DENKO CORPORATION, Ibaraki-shi, Osaka (JP)

(72) Inventors: Hiroto NISHII, Ibaraki-shi (JP); Taichi WATANABE, Ibaraki-shi (JP); Seiki TERAJI, Ibaraki-shi (JP); Kazunori KAWAMURA, Ibaraki-shi (JP); Takashi MINEMOTO, Kusatsu-shi (JP); Jakapan CHANTANA, Kusatsu-shi (JP); Masashi MURATA, Kusatsu-shi (JP)

(73) Assignee: NITTO DENKO CORPORATION, Ibaraki-shi, Osaka (JP)

(21) Appl. No.: 14/766,066

(22) PCT Filed: Jan. 24, 2014
(86) PCT No.: PCT/JP2014/051507

§ 371 Date: Aug. 5, 2015

(30) Foreign Application Priority Data
Feb. 12, 2013 (JP) 2013-024584

(51) Int. Cl. H01L 31/0749; H01L 31/032; H01L 31/18

(52) U.S. Cl. CPC H01L 31/0749; H01L 31/18; H01L 31/1864; H01L 31/1884; H01L 31/0322

(57) ABSTRACT

The present invention provides a CIGS film production method which ensures that a CIGS film excellent in conversion efficiency can be produced at lower costs with higher reproducibility, and a CIGS solar cell production method using the CIGS film production method. The CIGS film production method includes: a stacking step of stacking an (A) layer containing indium, gallium and selenium and a (B) layer containing copper and selenium in this order in a solid phase over a substrate while heating at a temperature of higher than 250° C. and not higher than 400° C.; and a heating step of further heating the resulting stack of the (A) layer and the (B) layer to melt a compound of copper and selenium in the (B) layer into a liquid phase, whereby copper is diffused from the (B) layer into the (A) layer to cause crystal growth to provide a CIGS film.

### TECHNICAL FIELD

The present invention relates to a CIGS film production method for producing a CIGS film to be used as a light absorbing layer for a CIGS solar cell to impart the CIGS solar cell with excellent characteristic properties by uniform diffusion of copper and uniform growth of crystal grains, and to a CIGS solar cell production method employing the CIGS film production method.

### BACKGROUND ART

Thin film solar cells typified by amorphous silicon solar cells and compound thin film solar cells allow for significant reduction in material costs and production costs as compared with conventional crystalline silicon solar cells. In recent years, therefore, research and development have been rapidly conducted on these thin film solar cells. Among these thin film solar cells, a CIGS solar cell which is a type of compound thin film solar cell produced by employing Group I, III and VI elements as constituents and including a light absorbing layer composed of an alloy of copper (Cu), indium (In), gallium (Ga) and selenium (Se) is particularly attractive, because the CIGS solar cell is excellent in sunlight conversion efficiency (hereinafter referred to simply as “conversion efficiency”) and is produced without the use of silicon.

The light absorbing layer of the CIGS solar cell is produced by a selenization method, a non-vacuum process (nano particle) method, a vacuum evaporation method or the like. In the vacuum evaporation method, the film is formed through vapor deposition by separately heating Cu, In, Ga and Se evaporation sources. Since the formation of the film is achieved by controlling the feed amounts of the respective elements, the composition of the film can be advantageously controlled along the thickness of the film.

A so-called three-step method, which is a type of multi-source evaporation method of the vacuum evaporation method, provides the highest conversion efficiency. As shown in FIG. 9, this method includes three steps. In the first step, In, Ga and Se are vapor-deposited on a substrate, whereby an (In, Ga)₂Se₃ film is formed. In the second step, the temperature of the substrate is increased to 550° C., and Cu and Se are vapor-deposited, whereby a Cu-rich CIGS film is formed. At this stage, two phases, i.e., liquid phase Cu₍₂₋ₓ₎Se and solid phase CIGS, coexist in the CIGS film, whereby crystal grain size is rapidly increased in the presence of Cu₍₂₋ₓ₎Se.

It is known that Cu₍₂₋ₓ₎Se has a lower resistance and, therefore, adversely influences solar cell characteristics. In the third step of the three-step method, therefore, In, Ga and Se are further vapor-deposited to reduce the proportion of Cu₍₂₋ₓ₎Se. Thus, the CIGS film has a composition slightly rich in Group III as a whole. The CIGS thin film thus formed by the three-step method has greater crystal grain diameters and yet has a thin film crystal structure having a crystallographically higher quality than a CIGS thin film produced by the conventional evaporation method (see, for example, PTL 1).

Where the CIGS film formed by the three-step method is used for a solar cell, the solar cell indeed has a higher conversion efficiency from a viewpoint of a smaller-area device. However, the CIGS film is produced by supplying liquid phase Cu₍₂₋ₓ₎Se (principal component for crystal growth) from the initial stage, so that Cu is not necessarily uniformly diffused into the film. In a strict sense, therefore, the crystal grains are not necessarily uniform. Further, Cu₍₂₋ₓ₎Se is easily excessively incorporated into the film. Problematically, this impairs the device characteristic properties.

### RELATED ART DOCUMENT

### Patent Document

PTL 1: JP-A-HEI10(1998)-513606

### SUMMARY OF INVENTION

In view of the foregoing, it is an object of the present invention to provide a CIGS film production method which ensures that a CIGS film even for use in production of a large-area device can be produced as having an excellent conversion efficiency at lower costs, and to provide a CIGS solar cell production method employing the CIGS film production method.

According to a first aspect of the present invention to achieve the aforementioned object, there is provided a CIGS film production method for producing a CIGS film to be used as a light absorbing layer for a CIGS solar cell, the method including: a stacking step of stacking an (A) layer containing indium, gallium and selenium and a (B) layer containing copper and selenium in this order in a solid phase over a substrate while heating at a temperature of higher than 250° C. and not higher than 400° C.; and a heating step of further heating the resulting stack of the (A) layer and the (B) layer to melt the (B) layer into a liquid phase, whereby copper is diffused from the (B) layer into the (A) layer to cause crystal growth to provide the CIGS film.

According to a second aspect of the present invention, there is provided a CIGS solar cell production method including the steps of: providing a rear electrode layer over a substrate; providing a light absorbing layer of a CIGS film; providing a buffer layer; and providing a transparent electrically-conductive layer; wherein the light absorbing layer of the CIGS film is formed by the CIGS film production method according to the first aspect in the light absorbing layer providing step.

The inventors of the present invention conducted studies on a compound semiconductor solar cell, particularly on a CIGS solar cell, in order to provide a solar cell having a higher light absorbing coefficient and effective for resource saving. As a result, the inventors found that, where the CIGS film serving as the light absorbing layer of the CIGS solar cell is produced, rather than by the conventional three-step method shown in FIG. 9, by first stacking the (A) layer containing In, Ga and Se and the (B) layer containing Cu and Se in this order in the solid phase over the substrate, then heating the resulting stack of the two layers (A) and (B) to melt a compound of Cu and Se in the (B) layer into the liquid phase to diffuse Cu from the (B) layer into the (A) layer to cause crystal growth to provide the CIGS film as shown in FIG. 1, crystal grains are uniformly grown to greater sizes in the film and an excess amount of Cu₍₂₋ₓ₎Se is prevented from being incorporated into the film. The inventors further conducted studies and found that, where the substrate is maintained at a substrate retention temperature of higher than 250° C. and not higher than 400° C. in the step of stacking the (A) layer and the (B) layer in the aforementioned production method, the resulting CIGS film has a crystal orientation such as to have a higher (220/204) peak intensity ratio in the X-ray diffraction, and attained the present invention.

In the present invention, the term “solid phase” means a phase in which a substance is in a solid state at a specific temperature, and the term “liquid phase” means a phase in which a substance is in a liquid state at a specific temperature.

In the present invention, the expression “the (A) layer and the (B) layer are stacked over the substrate” means not only that these layers are stacked directly on the substrate, but also that these layers are stacked over the substrate with the intervention of other layer.

In the inventive CIGS film production method, the (A) layer containing In, Ga and Se and the (B) layer containing Cu and Se are first stacked in this order over the substrate. At this time, the (A) layer and the (B) layer are stacked in the solid phase and, therefore, each have a uniform thickness. Then, the stack of these two layers (A) and (B) is heated to melt the compound of Cu and Se into the liquid phase in the (B) layer, whereby Cu is rapidly diffused from the (B) layer into the (A) layer. At this time, Cu is uniformly diffused from the (B) layer into the (A) layer, because the (B) layer is formed as having a uniform thickness on the (A) layer in the previous step. Thus, the crystal grains are uniformly grown to greater sizes. Since the (B) layer is once provided in the solid phase, Cu₍₂₋ₓ₎Se is substantially prevented from being excessively incorporated into the CIGS film. Therefore, the CIGS solar cell employing the CIGS film produced by this production method has a higher conversion efficiency substantially without device-to-device variations in conversion efficiency. In addition, Cu₍₂₋ₓ₎Se is not present in excess in the film, so that the cell characteristics are not adversely influenced.

The stacking step is performed with the substrate being heated to a temperature of higher than 250° C. and not higher than 400° C., so that the resulting CIGS film has a crystal orientation such as to have a higher (220/204) peak intensity ratio in the X-ray diffraction. Therefore, the CIGS film allows for production of a CIGS solar cell having an excellent pn junction and a higher conversion efficiency.

Where the heating step is performed at a temperature of not lower than 520° C., most of the compound of Cu and Se in the (B) layer is melted. Therefore, Cu is rapidly and uniformly diffused from the (B) layer into the (A) layer. Thus, the crystal grains are uniformly grown to greater sizes.

Where the temperature is increased at a temperature increasing rate of not less than 10° C./second from the temperature of the stacking step to the temperature of the heating step, the (B) layer is rapidly liquefied and, therefore, Cu is more rapidly diffused from the (B) layer into the (A) layer. Thus, the crystal grains are uniformly grown to greater sizes in the film.

Where Se vapor or hydrogen selenide (H₂Se) is supplied in the heating step and a Se partial pressure is maintained at a higher level in a front surface of the CIGS film than in an inner portion of the CIGS film, Se is substantially prevented from being released from the CIGS film in the heating step. Thus, the composition of the CIGS film can be more advantageously controlled.

The CIGS film may satisfy a molar ratio of 0.95<Cu/(In+Ga)<1.30 at the end of the heating step, and In, Ga and Se may be further vapor-deposited on the CIGS film after the heating step with the substrate maintained at the same temperature as in the heating step to allow the CIGS film to satisfy a molar ratio of 0.70<Cu/(In+Ga)<0.95. In this case, with the CIGS film having a composition satisfying a molar ratio of 0.95<Cu/(In+Ga)<1.30 at the end of the heating step, the Cu component is also sufficiently diffused in an interface between the (A) layer and the (B) layer to cause the crystal growth. In addition, Cu₍₂₋ₓ₎Se is prevented from being excessively incorporated into the CIGS film. Therefore, a device employing the CIGS film is free from reduction in device characteristics. Where In, Ga and Se are further vapor-deposited on the CIGS film after the heating step with the substrate maintained at the same temperature as in the heating step to allow the CIGS film to have a composition satisfying a molar ratio of 0.70<Cu/(In+Ga)<0.95, the CIGS film is slightly Cu-deficient as a whole. Therefore, where the CIGS film is used as a light absorbing layer for a device, the light absorbing layer has a higher efficiency.

In the present invention, the proportion of Cu based on the total amount of In and Ga in the CIGS film is calculated based on atomic number concentrations of Cu, In and Ga of the CIGS film determined by means of an energy dispersive fluorescent X-ray analyzer (EX-250 available from Horiba Corporation) or a D-SIMS (dynamic SIMS) evaluation apparatus (available from Ulvac-Phi, Inc.)

Where the CIGS solar cell production method includes the steps of providing the rear electrode layer, providing the light absorbing layer of the CIGS film, providing the buffer layer and providing the transparent electrically-conductive layer, and the light absorbing layer of the CIGS film is formed by the CIGS film production method according to the first aspect in the light absorbing layer providing step, the CIGS solar cell can be produced as having a sufficiently high conversion efficiency with higher reproducibility with smaller device-to-device variations in conversion efficiency.

### BRIEF DESCRIPTION OF DRAWINGS

FIG. 1 is a schematic diagram for explaining the present invention.

FIG. 2 is a diagram for explaining a CIGS film to be produced according to one embodiment of the present invention.

FIG. 3 is a diagram for explaining a production method for the CIGS film.

FIG. 4 is a diagram for explaining the CIGS film production method.

FIG. 5 is a diagram for explaining the CIGS film production method.

FIG. 6 is a diagram for explaining the CIGS film production method.

FIG. 7 is a temperature profile showing changes in temperature in respective steps of the CIGS film production method.

FIG. 8 is a diagram for explaining a CIGS solar cell to be produced according to another embodiment of the present invention.

FIG. 9 is a schematic diagram for explaining a conventional example.

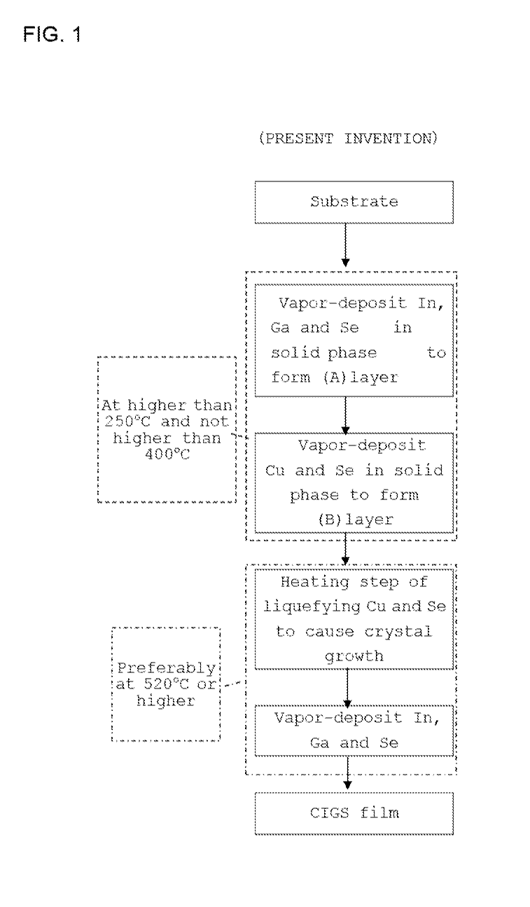

### DESCRIPTION OF EMBODIMENTS

Next, embodiments of the present invention will be described.

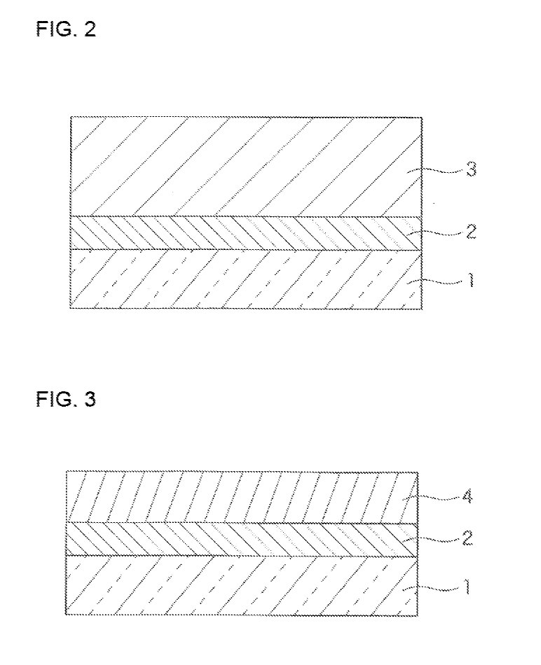

FIG. 2 is a diagram for explaining a CIGS film 3 to be produced according to one embodiment of the present invention. In FIG. 2, the CIGS film 3 is used as a light absorbing layer for a CIGS solar cell. A rear electrode layer 2 of molybdenum (Mo) is provided over a substrate 1 of soda lime glass (SLG), and the CIGS film 3 is provided over the rear electrode layer 2. These components will hereinafter be described in detail, and a method for producing the CIGS film 3 will also be described in detail. In FIG. 2, these components are schematically illustrated, and each have a thickness and a size that are different from the actual thickness and the actual size thereof. (The same is applied to the following figures.)

In FIG. 2, the substrate 1 serves as a support substrate and, other than SLG, a flexible metal foil or the like may be used as the substrate. A material capable of enduring a temperature of not lower than 520° C. is preferably used for the substrate 1 to withstand heating in the subsequent heating step.

The rear electrode layer 2 is formed by a sputtering method. Exemplary materials other than Mo for the rear electrode layer 2 include tungsten, chromium and titanium. The rear electrode layer 2 may have a single layer structure or a multilayer structure. The rear electrode layer 2 preferably has a thickness of 100 nm to 1000 nm.

The CIGS film 3 is made of a compound semiconductor containing four elements, i.e., Cu, In, Ga and Se, and has a thickness of 2.0 μm. Further, the CIGS film 3 has a molar ratio of Cu/(In+Ga)≈0.77 with a composition ratio of Cu:In:Ga=22.1:21.2:7.5.

The CIGS film 3 may be produced in the following manner. First, a substrate 1 formed with a rear electrode layer 2 is prepared and, as shown in FIG. 3, In, Ga and Se are vapor-deposited on the rear electrode layer 2 to form an (A) layer 4 over the rear electrode layer 2 with the substrate 1 maintained at a retention temperature of 330° C.

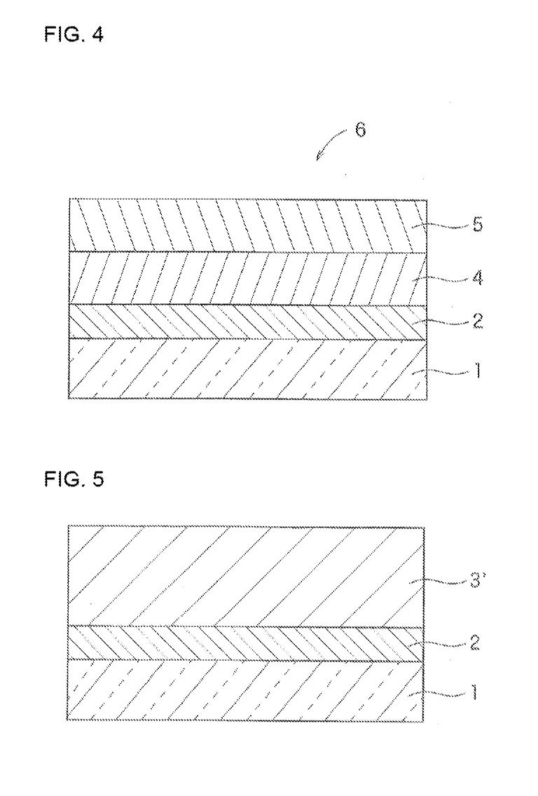

With the substrate 1 maintained at a retention temperature of 330° C., as shown in FIG. 4, Cu and Se are vapor-deposited on the (A) layer 4, whereby a stack 6 including the (B) layer 5 stacked on the (A) layer 4 is formed. At this time, the (A) layer 4 and the (B) layer 5 are each in a solid phase. Therefore, the crystal growth does not occur at this stage.

In turn, the stack 6 is further heated for 15 minutes with the substrate 1 maintained at a retention temperature of 550° C., while Se vapor is supplied by thermal sublimation. Thus, a compound of Cu and Se in the (B) layer 5 is melted into a liquid phase, whereby Cu is diffused from the (B) layer 5 into the (A) layer 4, in which the crystal growth occurs. At this time, the crystal growth occurs parallel to the substrate. In this heating step, the (A) layer 4 and the (B) layer 5 are unified into a CIGS film 3′ (see FIG. 5). At this time, the CIGS film 3′ has a molar ratio of Cu/(In+Ga)≈1.00 with a composition ratio of Cu:In:Ga=25.1:18.5:6.4.

The temperature is increased at a temperature increasing rate of 10° C./second from 330° C. for the stacking step to 550° C. for the heating step. If the temperature increasing rate is excessively low, the liquefaction of the (B) layer proceeds at a lower speed, making it impossible to rapidly diffuse Cu from the (B) layer into the (A) layer. This tends to prevent crystal grains from growing to greater sizes. Therefore, the temperature increasing rate is preferably not less than 10° C./second.

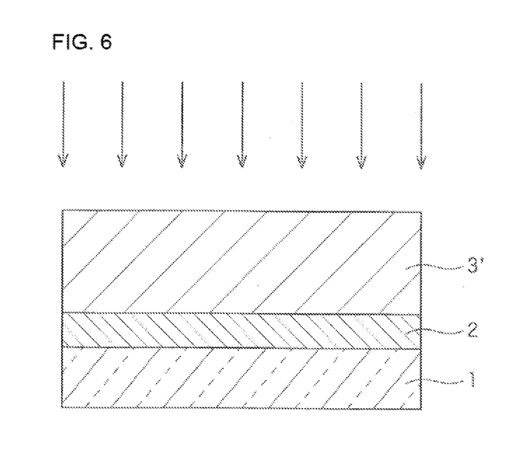

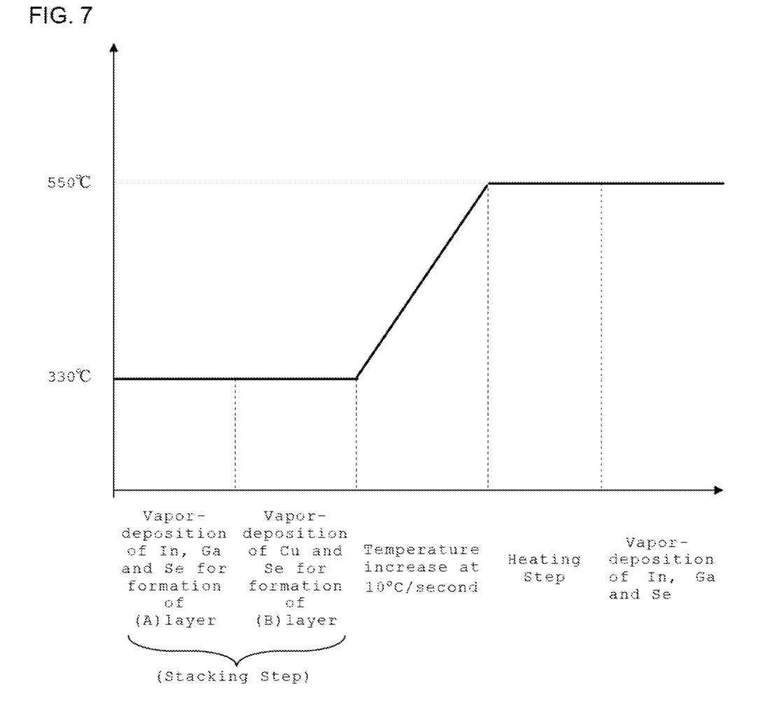

Then, as shown in FIG. 6, the CIGS film 3 (see FIG. 2) is produced by further vapor-depositing In, Ga and Se on the CIGS film 3′ including the (A) layer and the (B) layer unified together while maintaining the substrate 1 at a retention temperature of 550° C. (which is the same temperature as in the heating step) and supplying the thermally sublimated Se vapor to the CIGS film 3′. Thus, the CIGS film 3 is slightly Cu-deficient as a whole. The substrate retention temperature profile in this embodiment is shown in FIG. 7.

In the CIGS film production method, as described above, the (A) layer 4 containing In, Ga and Se and the (B) layer 5 containing Cu and Se are first stacked in this order over the substrate 1 at a temperature of 330° C., and then the stack 6 of the (A) layer 4 and the (B) layer 5 is heated for 15 minutes with the substrate 1 maintained at a retention temperature of 550° C. Thus, the compound of Cu and Se in the (B) layer 5 is melted into the liquid phase, whereby Cu is rapidly diffused from the (B) layer 5 into the (A) layer 4. Therefore, Cu can be uniformly diffused from the (B) layer 5 into the (A) layer 4, whereby the CIGS film 3′ is produced as containing crystal grains uniformly grown to greater sizes. Since the (B) layer 5 containing Cu is once provided in the solid phase, Cu₍₂₋ₓ₎Se is substantially prevented from being excessively incorporated into the film. The (A) layer and the (B) layer are stacked with the substrate 1 maintained at a retention temperature of 330° C., so that the CIGS film has a crystal orientation such as to have a higher (220/204) peak intensity ratio in the X-ray diffraction. Since the thermally sublimated Se vapor is supplied in the heating step, Se is substantially prevented from being released outside the system in the heating step. Thus, the Cu—In—Ga composition ratio of the CIGS film 3′ can be controlled as desired. Further, In, Ga and Se are vapor-deposited on the CIGS film 3′ at substantially the same temperature (not lower than 550° C.) as in the heating step to produce the CIGS film 3. Thus, the CIGS film 3 is slightly Cu-deficient as a whole. Therefore, where the CIGS film 3 is used as a light absorbing layer for a device, the light absorbing layer has a higher efficiency.

In the embodiment described above, the formation of the (A) layer 4 and the (B) layer 5 is achieved with the substrate 1 maintained at a retention temperature of 330° C. not by way of limitation, but the retention temperature may be higher than 250° C. and not higher than 400° C. The retention temperature is preferably a temperature of 270° C. to 380° C., more preferably a temperature of 280° C. to 350° C. If the temperature is excessively high, it will be impossible to stack the (B) layer 5 in the solid phase over the (A) layer 4. If the temperature is excessively low, on the other hand, it will be difficult to provide a specific crystal orientation.

In the embodiment described above, the stack 6 of the (A) layer 4 and the (B) layer 5 is heated for 15 minutes with the substrate 1 maintained at a retention temperature of 550° C. not by way of limitation. The retention temperature for the heating is preferably not lower than 520° C. The heating period is preferably 1 to 30 minutes, more preferably 2 to 15 minutes. This is because a certain period is required for sufficient crystal growth, although Cu is very rapidly diffused from the (B) layer 5 into the (A) layer 4.

In the embodiment described above, In, Ga and Se are further vapor-deposited on the CIGS film 3′ obtained after the heating step with the substrate 1 maintained at a retention temperature of 550° C. but, where a layer of Cu and Se unincorporated into the film is not exposed in the outermost layer of the CIGS film 3′, there is no need to further vapor-deposit In, Ga and Se. However, sufficient crystal growth can be ensured without the formation of the Cu—Se phase in the film by further vapor-depositing In, Ga and Se on the CIGS film 3′ obtained after the heating step. In addition, the CIGS film 3 is easily made slightly Cu-deficient. Therefore, the further vapor-deposition of In, Ga and Se is preferred.

In the embodiment described above, the CIGS film 3′ obtained after the heating step has a molar ratio of Cu/(In+Ga)≈1.00 with a composition ratio of Cu:In:Ga=25.1:18.5:6.4 not by way of limitation, but may have a desired composition ratio. However, the Cu—In—Ga composition ratio of the CIGS film 3′ is preferably such as to satisfy an expression of 0.95<Cu/(In+Ga)<1.30 (molar ratio). If the Cu/(In+Ga) value is excessively small, the sufficient crystal growth tends to be prevented due to Cu deficiency. If the Cu/(In+Ga) value is excessively great, on the other hand, Cu₍₂₋ₓ₎Se is excessively incorporated into the CIGS film 3′. Therefore, where the CIGS film 3′ is used for a device, the device is liable to have poorer device characteristics.

In the embodiment described above, the CIGS film 3 has a molar ratio of Cu/(In+Ga)≈0.77 with a composition ratio of Cu:In:Ga=22.1:21.2:7.5 not by way of limitation, but may have a desired composition ratio. However, the molar ratio preferably satisfies an expression of 0.70<Cu/(In+Ga)<0.95. In this case, Cu₍₂₋ₓ₎Se can be prevented from being excessively incorporated into the CIGS film 3, and the CIGS film 3 is slightly Cu-deficient as a whole. Further, the ratio of Ga and In, which are the same group elements, is preferably 0.10<Ga/(In+Ga)<0.40.

In the embodiment described above, the CIGS film 3 has a thickness of 2.0 μm not by way of limitation, but may have a desired thickness. However, the thickness of the CIGS film 3 is preferably 1.0 to 3.0 μm, more preferably 1.5 to 2.5 μm. If the thickness is excessively small, the CIGS film serving as the light absorbing layer has a smaller light absorbing amount, thereby impairing the performance of the device. If the thickness is excessively great, on the other hand, a longer period is required for the formation of the film, thereby reducing the productivity.

In the embodiment described above, the Se vapor is supplied in the heating step and in the In, Ga and Se vapor-depositing step subsequent to the heating step. Instead of the Se vapor, H₂Se may be supplied. In this case, the supply of H₂Se provides the same effect as the supply of the Se vapor. Where a minimum amount of Se is released outside the CIGS film 3′ and the CIGS film 3, there is no need to supply the Se vapor and H₂Se.

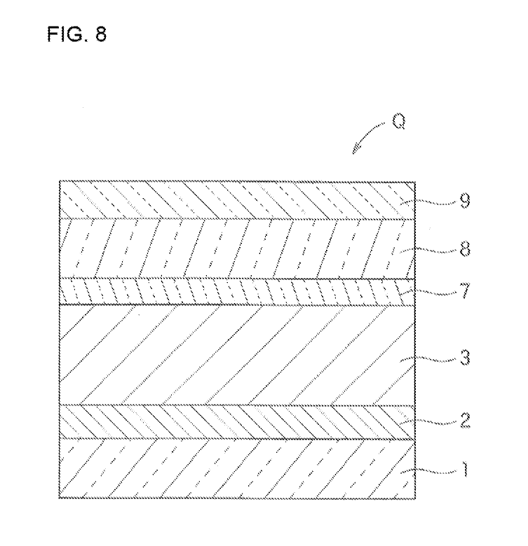

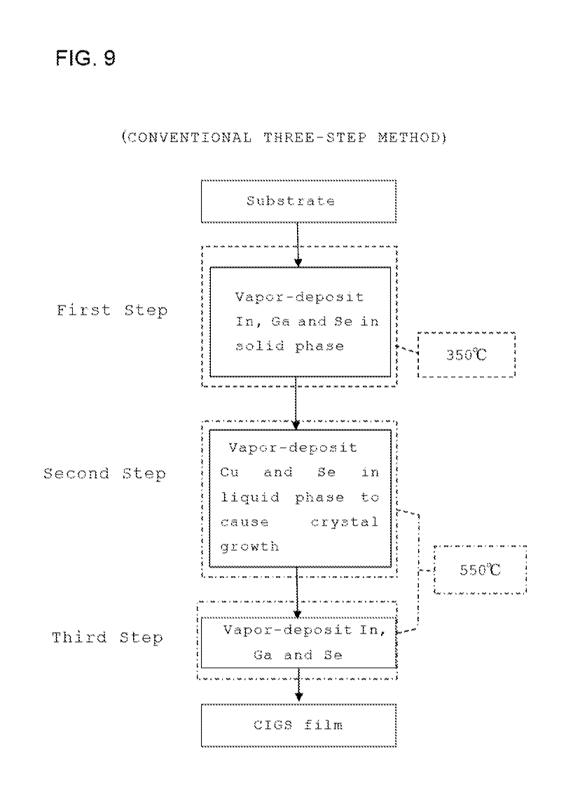

Next, the construction of a CIGS solar cell Q employing the thus produced CIGS film 3 as a light absorbing layer and a production method for the CIGS solar cell Q will be described below. As shown in FIG. 8, the CIGS solar cell Q includes the CIGS film 3, and a buffer layer 7, a buffer layer 8 and a transparent electrically-conductive layer 9 stacked in this order over the CIGS film 3.

More specifically, a buffer layer 7 of cadmium sulfide (CdS) (having a thickness of 50 nm) is formed over the CIGS film 3 formed in the aforementioned manner by a chemical bath deposition (CBD) method. Further, a buffer layer 8 of ZnO (having a thickness of 50 nm) is formed on the buffer layer 7 by a sputtering method. These buffer layers 7, 8 are preferably made of a higher-resistance n-type semiconductor so as to form a pn junction with the CIGS film 3. A single buffer layer such as of ZnMgO or Zn(O,S) may be used instead of the CdS buffer layer and the ZnO buffer layer. The buffer layers 7, 8 each preferably have a thickness of 30 to 200 nm. Where the buffer layer has a single layer structure, the single buffer layer preferably has a thickness of 30 to 200 nm. As described above, the buffer layer 7 may be formed by a solution method such as the CBD method, and the buffer layer 8 may be formed by a vacuum film formation method such as the sputtering method. The plural types of buffer layers thus stacked advantageously form the pn junction with the CIGS film 3. If the pn junction can be properly formed, the plural types of buffer layers are not necessarily required.

Then, a transparent electrically-conductive film 9 of indium tin oxide (ITO) (having a thickness of 200 nm) is formed over the buffer layer 8 by a sputtering method. The transparent electrically-conductive layer 9 is preferably made of a material having a higher transmittance. Examples of the material other than ITO include indium zinc oxide (IZO) and aluminum zinc oxide (Al:ZnO). The transparent electrically-conductive film 9 preferably has a thickness of 100 to 300 nm. In this manner, the CIGS solar cell Q is produced, which includes the rear electrode layer 2, the CIGS film 3, the buffer layer 7, the buffer layer 8 and the transparent electrically-conducive layer 9 stacked in this order over the substrate 1.

In the CIGS solar cell production method, as described above, the CIGS film 3 produced by the aforementioned special process is used as the light absorbing layer. Therefore, the CIGS solar cell Q can be produced as having a higher conversion efficiency substantially without device-to-device variations in conversion efficiency. In addition, Cu₍₂₋ₓ₎Se is not formed in excess in the CIGS film 3 serving as the light absorbing layer, so that the CIGS solar cell Q is free from reduction in cell characteristics and has a higher efficiency. Since the CIGS film 3 is slightly Cu-deficient as a whole, the CIGS solar cell has a higher efficiency. The CIGS film has a crystal orientation such as to have a higher (220/204) peak intensity ratio in the X-ray diffraction. Therefore, the CIGS solar cell has an excellent pn junction to thereby have a further higher conversion efficiency.

In the embodiment described above, the CIGS solar cell Q includes the substrate 1, the rear electrode layer 2, the CIGS film 3, the buffer layer 7, the buffer layer 8 and the transparent electrically-conductive layer 9. As required, a metal electrode may be provided on the transparent electrode layer 9.

Next, inventive examples will be described in conjunction with comparative examples. It should be understood that the present invention be not limited to these inventive examples.

### EXAMPLES

### Example 1

A CIGS solar cell was produced in the same manner as in the embodiment described above. More specifically, a SLG substrate (having a size of 30×30 mm and a thickness of 0.55 mm) was prepared as a substrate 1, and Mo was deposited (to a thickness of 500 nm) over the substrate 1 to form a rear electrode layer 2. While the substrate 1 was maintained at a retention temperature of 255° C., In, Ga and Se were vapor-deposited to form an (A) layer. In turn, with the substrate 1 maintained at a retention temperature of 255° C., Cu and Se were vapor-deposited on the (A) layer to form a (B) layer. Thus, a stack 6 was formed. While a very small amount of Se vapor was supplied to the stack 6, the substrate 1 was heated to be maintained at a retention temperature of 550° C. for 15 minutes to cause crystal growth. Thus, a CIGS film 3′ was produced. While a very small amount of Se gas was supplied to the CIGS film 3′ with the substrate 1 maintained at a retention temperature of 550° C., In, Ga and Se were vapor-deposited. Thus, an intended CIGS film 3 (having a thickness of 2.0 μm) was produced. The CIGS solar cell of Example 1 was produced by employing the CIGS film 3 thus produced.

### Examples 2 to 6 and Comparative Examples 1 to 3

CIGS solar cells were each produced in substantially the same manner as in Example 1, except that the substrate 1 was maintained at a retention temperature shown below in Table 1 in the formation of the (A) layer and the (B) layer.

Ten such CIGS solar cells were produced for each of Examples and Comparative Examples. Then, the conversion efficiencies of the CIGS solar cells were each measured in the following manner, and an average conversion efficiency was calculated. The crystal characteristics of the CIGS film used for each of Examples and Comparative Examples were measured by means of an X-ray diffraction analyzer, and a peak intensity ratio was calculated. The results are also shown below in Table 1.

[Conversion Efficiency]

For each of Examples and Comparative Examples, the conversion efficiency of the CIGS solar cell was measured by applying artificial sunlight (AM1.5) to an area over the front surface of the CIGS solar cell by means of a solar simulator (CELL TESTER YSS150 available from Yamashita Denso Corporation).

[X-Ray Diffraction]

For each of Examples and Comparative Examples, the crystal orientation was measured by means of an X-ray diffraction analyzer. Then, a (220/204) peak intensity ratio (220/204)/(112) with respect to a (112) peak intensity was calculated. The X-ray diffraction was analyzed with a fixed incident angle of 5 degrees at a detector scanning rate of 3 degrees/minute by means of a Bruker's system XRD D8 DISCOVER with GADTS.

TABLE 1

| | Substrate | (220/204)/(112) | Average |
|---|---|---|---|
| | temperature | peak intensity | conversion |
| | (° C.) | ratio | efficiency (%) |
| Example 1 | 260 | 0.43 | 14.9 |
| Example 2 | 270 | 0.51 | 15.4 |
| Example 3 | 290 | 0.56 | 15.6 |
| Example 4 | 330 | 1.23 | 15,9 |
| Example 5 | 360 | 1.19 | 15.7 |
| Example 6 | 400 | 0.97 | 15.3 |
| Comparative Example 1 | 240 | 0.29 | 14.4 |
| Comparative Example 2 | 420 | 0.38 | 14.5 |
| Comparative Example 3 | 500 | 0.25 | 13.6 |

The above results indicate that the CIGS films of the CIGS solar cells of Examples 1 to 6 each had a (220/204)/(112) peak intensity ratio of 0.43 to 1.23 and an average conversion efficiency of 14.9% or higher. This indicates that the inventive production method makes it possible to produce a solar cell having a higher efficiency with proper reproducibility. On the other hand, the CIGS films of the CIGS solar cells of Comparative Examples 1 to 3 each had a (220/204)/(112) peak intensity ratio of 0.25 to 0.38 and a slightly lower average conversion efficiency on the order of 13.3 to 14.5%.

While specific forms of the embodiment of the present invention have been shown in the aforementioned inventive examples, the inventive examples are merely illustrative of the invention but not limitative of the invention. It is contemplated that various modifications apparent to those skilled in the art could be made within the scope of the invention.

The inventive CIGS film production method is suitable for producing a CIGS film having excellent characteristic properties for use as a light absorbing layer for a CIGS solar cell with proper reproducibility. The inventive CIGS solar cell production method is suitable for producing a solar cell having a higher conversion efficiency with proper reproducibility.

What is claimed is:

1. A CIGS film production method for producing a CIGS film to be used as a light absorbing layer for a CIGS solar cell, the method comprising:
a stacking step of stacking an (A) layer containing indium, gallium and selenium and a (B) layer containing copper and selenium in this order in a solid phase over a substrate while heating at a temperature of higher than 250° C. and not higher than 4000° C.; and
a heating step of further heating a resulting stack of the (A) layer and the (B) layer to melt the (B) layer into a liquid phase, whereby copper is diffused from the (B) layer into the (A) layer to cause crystal growth to provide the CIGS film.

2. The CIGS film production method according to claim 1, wherein the heating step is performed at a temperature of not lower than 520° C.

3. The CIGS film production method according to claim 1, wherein a temperature increasing rate of not less than 10° C./second is employed for temperature increase from the temperature of the stacking step to the temperature of the heating step.

4. The CIGS film production method according to claim 1, wherein selenium vapor or hydrogen selenide is supplied in the heating step, and a selenium partial pressure is maintained at a higher level in a front surface of the CIGS film than in an inner portion of the CIGS film.

5. The CIGS film production method according to claim 1,
wherein the CIGS film satisfies a molar ratio of 0.95<copper/(indium+gallium)<1.30 at the end of the heating step, and
wherein indium, gallium and selenium are further vapor-deposited on the CIGS film after the heating step with the substrate maintained at the same temperature as in the heating step to allow the CIGS film to satisfy a molar ratio of 0.70<copper/(indium+gallium)<0.95.

6. A CIGS solar cell production method comprising the steps of:
providing a rear electrode layer over a substrate;
providing a light absorbing layer of a CIGS film;
providing a buffer layer; and
providing a transparent electrically-conductive layer;
wherein the light absorbing layer of the CIGS film is formed by the CIGS film production method according to claim 1 in the light absorbing layer providing step.
